(19) United States
(12) Patent Application Publication
(10) Pub. No.: US 2007/0121307 A1
(43) Pub. Date: May 31, 2007

(54) EMI/RFI shield for electronic device

(75) Inventors: Qing Yang, Shenzhen (CN); Chia-Hua Chen, Tu-cheng (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FIH CO.,LTD, Shindian City (TW)

(21) Appl. No.: 11/478,412

(22) Filed: Jun. 28, 2006

(30) Foreign Application Priority Data
Nov. 25, 2005 (CN) 200510101786.7

(51) Int. Cl. H05K 9/00

(52) U.S. Cl. 361/818

(57) ABSTRACT

A shield (30) for shielding electronic components mounted on a printed circuit board (20) disposed within a housing (10) for an electronic device. The shield includes a top wall (32) and a circumferential sidewall (34). The circumferential sidewall extends from peripheral edges of the top wall toward a side of the top wall. The circumferential sidewall and the top wall cooperatively form a shield cavity (38) for shielding electronic the electronic components provided on the printed circuit board. The shield is integrally formed with an inner surface of the housing.

### TECHNICAL FIELD

The present invention relates to shields for shielding electronic components on a printed circuit board, and particularly to an EMI shield easily assembled to and detached from a printed circuit board of an electronic device.

### BACKGROUND

Electronic devices are subject to external EMI (electromagnetic interference) and/or RFI (radio frequency interference) which can result in signal distortion. Thus, EMI sensitive electronic components on a printed circuit board of a electronic device are conventionally protected from EMI by a shield. Referring to FIG. 5, an EMI shield in a electronic device (not labeled) comprises a shield 51 soldered onto a printed circuit board (PCB) 52 to shield electronic components (not labeled) on the PCB 52. An upper cover 50 and a lower cover 53 are assembled together to enclose the PCB 52 and the shield 51 therein. The shield 51 is needs to be fixed on the PCB 52 via a soldering process, which can be difficult. Furthermore, in order to replace or repair the electronic components, the shield must be de-soldered (i.e. the solder must be removed) before the shield can be safely detached from the PCB 52. This makes any repairs inconvenient and cumbersome.

U.S. Pat. No. 5,748,455 disclosed one solution to the problem mentioned above. Referring to FIG. 6, a lower cover 67 forms a plurality of posts 69 therein, each post defining a threaded hole (not labeled) therethrough for engaging with a corresponding screw 70. A PCB 71 defines a plurality of threaded holes 62 corresponding to the posts 69. A shield 63 defines a plurality of cutouts 66 at edges thereof for fitting the periphery of the posts 69. A plurality of spring pieces 64 extends out from edges of the shield 63, and a plurality of retaining pieces 65 perpendicularly project from edges of the shield 63 adjacent to the spring pieces 64. In assembly, the spring pieces 64 abut the PCB 61, and the retaining pieces 65 abut an inner wall 68 of the lower cover 67 and the PCB 61. The screws 70 are extended through the posts 69 and the threaded holes 62 of the PCB 61 and are secured in an upper cover 60. Therefore, the upper and lower covers 60, 67, the shield 63 and the PCB 61 are fixedly assembled together.

However, the above-described art comprising posts, threaded holes, screws, spring pieces, and retaining pieces, is unduly complicated and cumbersome. The shield is designed to shield the entire PCB, whereas only certain components on the PCB need be shielded to obtain the desired protection from external EMI.

What is needed, therefore, is an EMI shield which overcomes the above-described shortcomings.

### SUMMARY

In one embodiment thereof, a shield for shielding electronic components mounted on a printed circuit board (PCB) disposed within a housing for an electronic device is provided. The shield includes a top wall and a circumferential sidewall. The circumferential sidewall extends from peripheral edges of the top wall towards a side of the top wall. The circumferential sidewall and the top wall cooperatively form a shield cavity for shielding the electronic components provided on the printed circuit board. The shield is integrally formed with an inner surface of the housing.

Other advantages and novel features of the preferred embodiments of the present shield and its applications will become more apparent from the following detailed description when taken in conjunction with the accompanying drawings.

### BRIEF DESCRIPTION OF THE DRAWINGS

Many aspects of the present EMI shields and their applications can be better understood with reference to the following drawings. The components in the drawings are not necessarily drawn to scale, the emphasis instead being placed upon clearly illustrating the principles of the EMI shields. Moreover, in the drawings, like reference numerals designate corresponding parts throughout the several views.

FIG. 1 is a partially exploded, perspective view illustrating a mobile phone, to which an EMI shield according to a preferred embodiment is applied;

FIG. 2 is a perspective view illustrating the mobile phone illustrated in FIG. 1;

FIG. 3 is a partially perspective, assembled view of the mobile phone;

FIG. 4 is a cross-sectional view taken along VI-VI line of FIG. 3;

FIG. 5 is an isometric view of a typical EMI shield; and

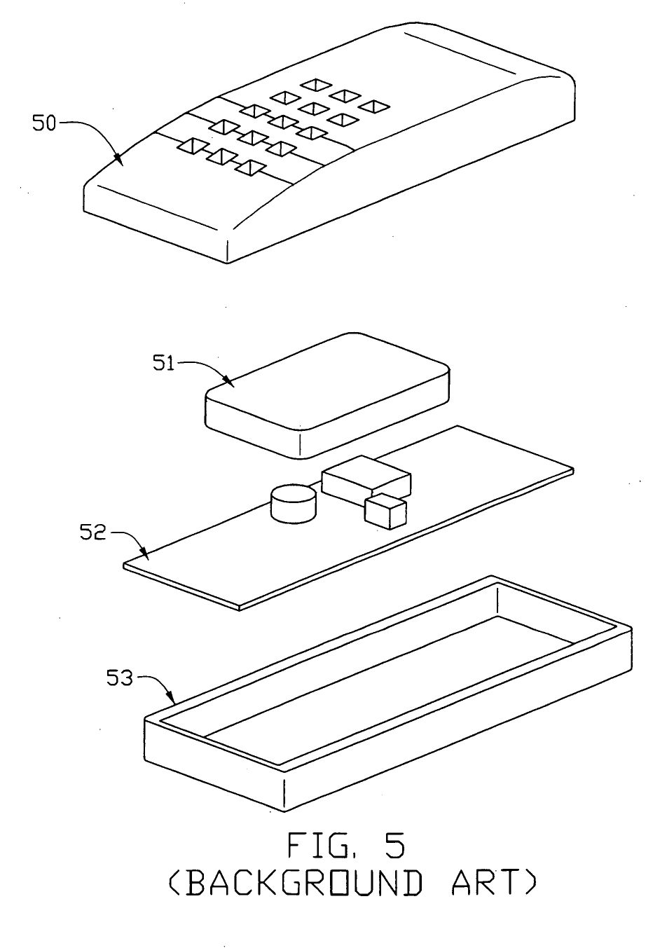

FIG. 6 is an isometric view of another typical EMI shield.

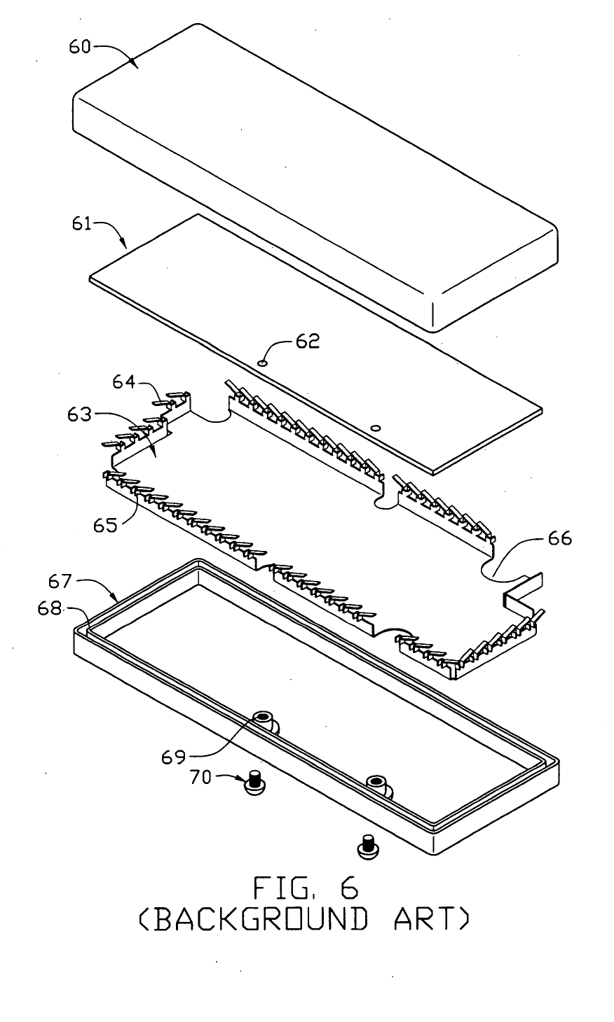

### DETAILED DESCRIPTION OF PREFERRED EMBODIMENTS

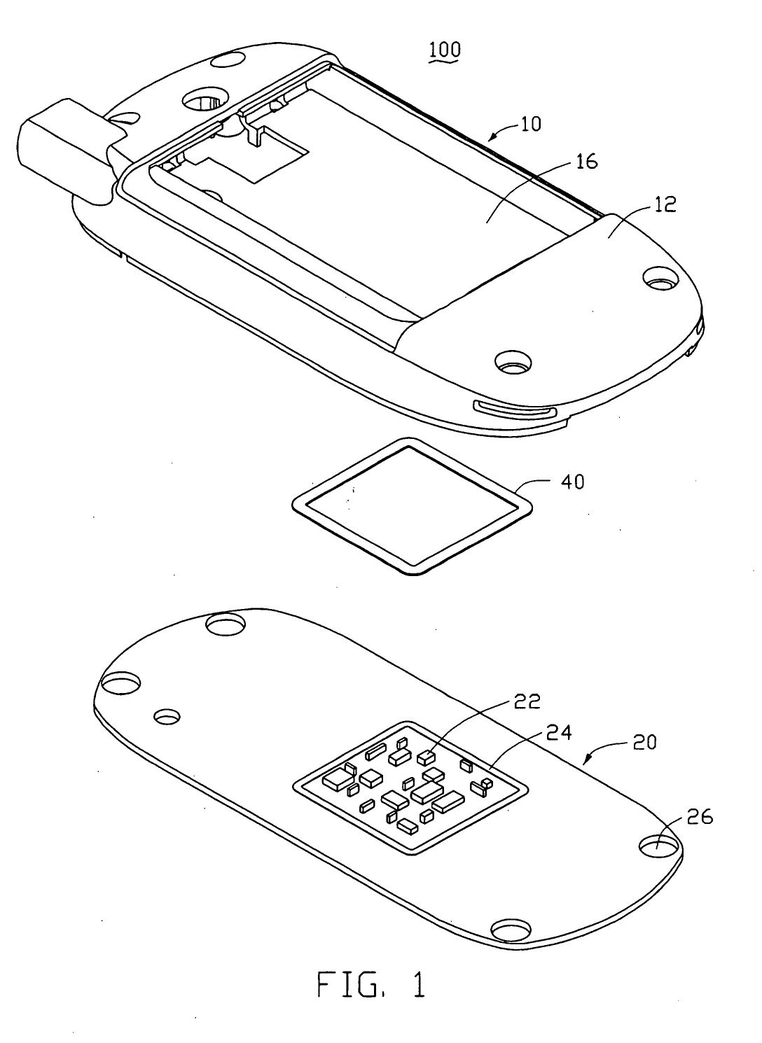

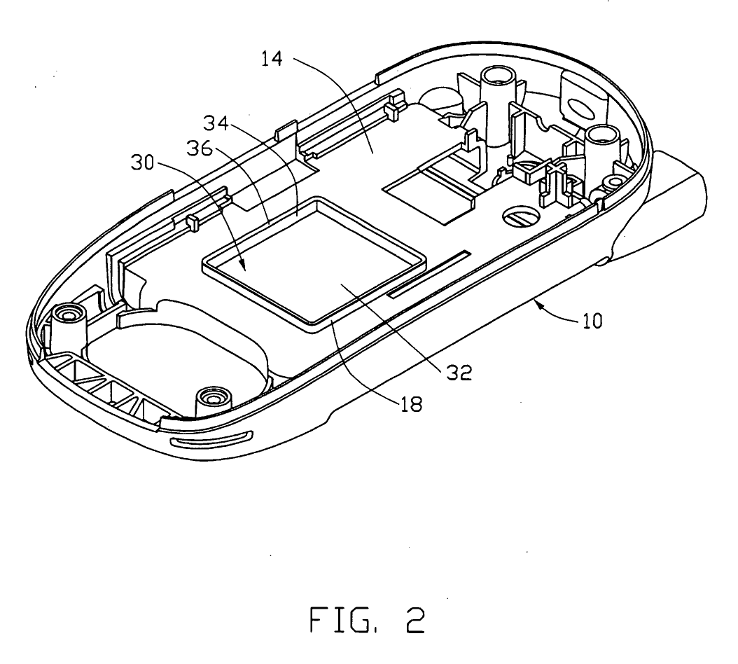

An EMI shield according to a preferred embodiment of the present invention is adapted for use in an electronic device such as a mobile phone 100. Referring to FIGS. 1 and 2, the mobile phone 100 includes an upper housing 10, a printed circuit board (PCB) 20, and an EMI shield 30. The PCB 20 has electronic components 22 and, a ground trace 24 surrounding the electronic components 22 and disposed on the PCB 20. The PCB 20 defines mounting holes 26 adjacent to two ends thereof, for mounting the PCB 20 to the upper housing 10. The shield 30 is used for providing EMI and/or RFI (radio frequency interference) shielding for electronic and electrical circuitry disposed on a printed circuit board (PCB).

The housing 10 could be the outer plastic cover of a radiotelephone, or other such housing. The housing 10 includes an upper surface 12, and a lower surface 14. The housing 10 has a compartment 16 defined in upper surface 12 thereof. The housing 10 has a square circumferential protrusion extending from the lower surface 14 thereof.

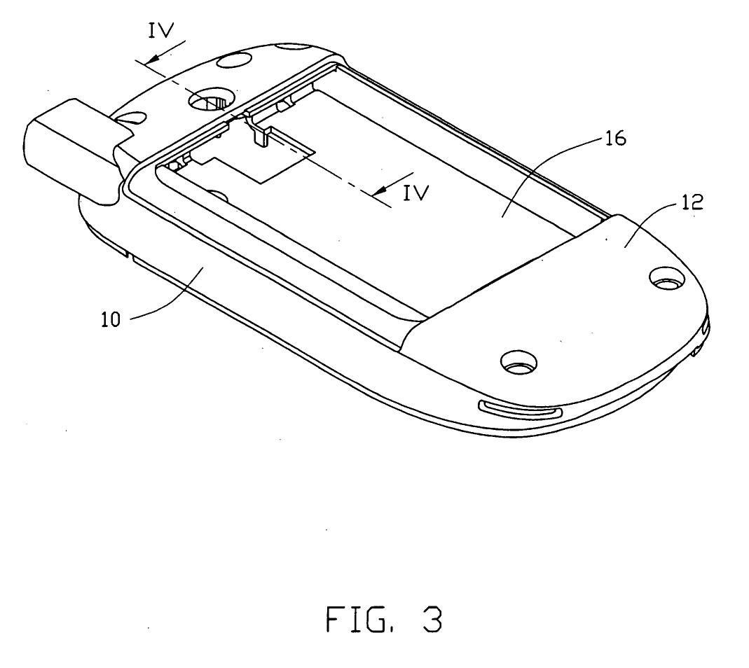

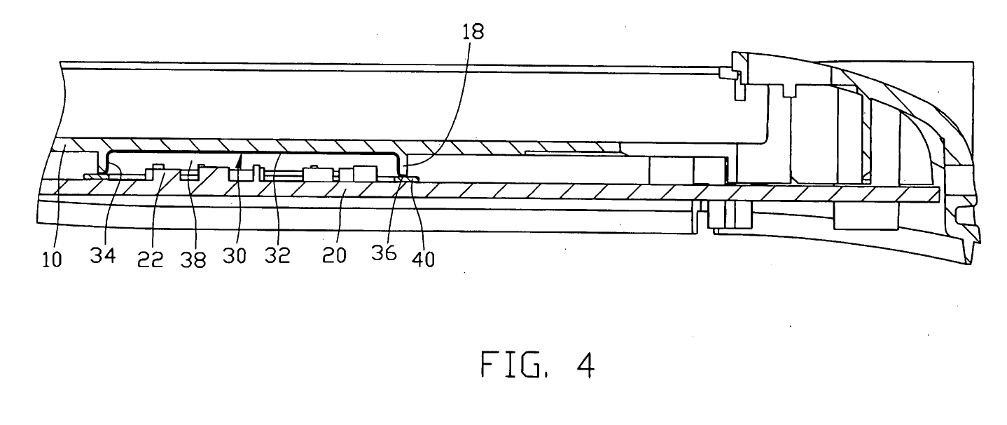

Referring to FIGS. 3 and 4, the shield 30 includes a top wall 32, a circumferential sidewall 34, and a circumferential flange 36. The top wall 32 and the circumferential sidewall 34 cooperatively form a shielding cavity 38. The shield 30 is preferably a conductive sheet. The shield 30 may be integrally formed on the housing 10 and joined with an inner surface of the circumferential protrusion 18 by in-mold laminating. The shield 30 may be formed by means of punching a conductive sheet, then be integrally formed on the housing 10 by means of insert molding. The shield 30 is thus substantially lower in cost, simpler in construction, and light in weight.

In assembly, a conductive adhesive such as an electrically conductive rubber 40 is applied on the ground trace 24. The PCB 20 is assembled on the lower surface 14 of the housing 10 via the mounting holes 26, with the electronic components 22 facing the lower surface 14 of the housing 10, and the circumferential flange 36 of the shield 30 compressing on the electrically conductive rubber 40. The electronic components 22 are received in the shield cavity 38 of the shield 30.

In alternative embodiment, the flange 36 may be omitted. The sidewalls 34 of the shield 30 can directly connect with the conductive rubber 40. The flange 36 may directly connect with the ground trace 24, thus the conductive rubber 40 may be omitted.

It is believed that the embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A shield for shielding electronic components mounted on a printed circuit board (PCB) disposed within a housing for an electronic device from electromagnetic interference and/or radio frequency interference, the shield comprising:
a top wall; and
a circumferential sidewall extending from the top wall, the circumferential sidewall and the top wall cooperatively forming a shield cavity for shielding the electronic components provided on the printed circuit board, the shield being integrally formed with an inner surface of the housing.

2. The shield as claimed in claim 1, wherein the shield is a conductive sheet, and the conductive sheet is integrally formed with the housing by means of in-mold laminating.

3. The shield as claimed in claim 1, wherein the shield is formed by means of punching a conductive thin flake, and the punched conductive thin flake being integrally formed with the housing via insert molding.

4. The shield as claimed in claim 3, further comprising a circumferential flange extending from the circumferential sidewall outwards.

5. A housing assembly for use with an electronic device comprising a printed circuit board containing electronic components, the housing assembly comprising:
a housing including a circumferential protrusion protruding from an inner surface thereof; and
a conductive shield having a shape corresponding to the peripheral walls of the housing and joined with an inner surface of the peripheral walls, the shield comprising:
a top wall;
a circumferential sidewall extending from peripheral edges of the top wall toward a side of the top wall, the circumferential sidewall and the top wall cooperatively forming a shield cavity for shielding the electronic components provided on the printed circuit board.

6. The housing assembly as claimed in claim 5, wherein the shield is integrally formed with the housing.

7. The housing assembly as claimed in claim 5, wherein the shield is a conductive sheet, and the conductive sheet is integrally formed with the housing by means of in-mold laminating.

8. The housing assembly as claimed in claim 5, wherein the shield is formed by means of punching a conductive thin flake, and the punched conductive thin flake being integrally formed with the housing via insert molding.

9. The housing assembly as claimed in claim 5, further comprising a circumferential flange extending from the circumferential sidewall outward and joined with a distal end of the circumferential protrusion.

10. TAn electronic device, comprising:
a housing including a circumferential protrusion protruding from an inner surface thereof,
a printed circuit board mounted on the housing; and
a conductive shield having a shape corresponding to the circumferential protrusion of the housing and joined with an inner surface of the peripheral protrusion, the shield seated upon the printed circuit board and including a top wall and a circumferential sidewall to enclose electronic components mounted on the printed circuit board.

11. The electronic device as claimed in claim 10, wherein circumferential sidewall extends from peripheral edges of the top wall toward a side of the top wall, the circumferential sidewall and the top wall cooperatively forming a shield cavity for shielding the electronic components provided on the printed circuit board.

12. The electronic device as claimed in claim 10, wherein the shield is integrally formed with the housing.

13. The electronic device as claimed in claim 12, wherein the shield is a conductive sheet, and the conductive sheet is integrally formed with the housing by means of in-mold laminating.

14. The electronic device as claimed in claim 12, wherein the shield is formed by means of punching a conductive thin flake, and the punched conductive thin flake being integrally formed with the housing via insert molding.

15. The electronic device as claimed in claim 10, further comprising a circumferential flange extending from the circumferential sidewall outward and joined with a distal end of the circumferential protrusion.

16. The electronic device as claimed in claim 10, further comprising an electrically conductive adhesive disposed on the printed circuit board and surrounding the electronic components for electrically coupling the shield to a predetermined electrical potential.

17. The electronic device as claimed in claim 16, wherein the electrically conductive adhesive is an electrically conductive rubber.
